(19) United States
(12) Patent Application Publication
(10) Pub. No.: US 2026/0090036 A1
(43) Pub. Date: Mar. 26, 2026

(54) ZENER DIODE AND MANUFACTURING METHOD

(71) Applicant: PANSTAR SEMICONDUCTOR CO., LTD., Hsinchu (TW)

(72) Inventor: I-Hua LIN, Hsinchu (TW)

(21) Appl. No.: 19/335,056

(22) Filed: Sep. 22, 2025

(30) Foreign Application Priority Data
Sep. 23, 2024 (TW) 113135950

(51) Int. Cl. H10D 62/10; H10D 8/01; H10D 8/25

(52) U.S. Cl. CPC H10D 62/107; H10D 8/022; H10D 8/25; H10D 62/117

(57) ABSTRACT

The present invention provides a Zener diode and a manufacturing method, which includes: a substrate; a buried layer formed on at least a part of a first surface of the substrate; an epitaxial layer formed on at least the buried layer; and a diffusion layer formed on at least the epitaxial layer; wherein there is a distance between the diffusion layer and the buried layer.

### CROSS-REFERENCE TO RELATED APPLICATION

This application claims the priority benefit of Taiwan application serial no. 113135950 filed on Sep. 23, 2024. The entirety of the above-mentioned patent applications is hereby incorporated by reference herein and made a part of this specification.

### FIELD

The present invention relates to a Zener diode and a manufacturing method thereof.

### BACKGROUND

Zener diodes have the characteristic of reverse breakdown. In the reverse breakdown state, the breakdown voltage between their two terminals is a specific value, which makes them suitable as voltage sources, electrostatic discharge (ESD) protection components, etc.

When manufacturing Zener diodes, in order to avoid the edge effect that causes the breakdown voltage to occur at the corners, a buried layer is generally used to increase the concentration of the planar junction at the bottom of the Zener diode, reduce the planar junction breakdown voltage, and cause the Zener diode breakdown to occur at the planar junction (i.e., the junction between the buried layer and the diffusion layer). However, the concentration distributions of the diffusion layer and the buried layer are both steep, so the breakdown voltage of a traditional Zener diode controlled by the buried layer is very sensitive to process variation and drift. In addition, since an ion implantation machine has its processing capability limit, the adjustment range of the breakdown voltage of a Zener diode controlled by the buried layer is therefore limited, making it not being able to be applied to extremely high breakdown voltages and the process control difficult.

Therefore, a Zener diode with better adjustment of breakdown voltage and easier process control is needed.

### SUMMARY

One of the purposes of the present invention is to make the manufacturing process of a Zener diode easier to control and the electrical characteristics of a Zener diode less susceptible to the influence of manufacturing process drift.

One of the purposes of the present invention is to make a Zener diode have the characteristics of low capacitance and high breakdown voltage.

One of the purposes of the present invention is to improve the anti-static discharge capability of a Zener diode.

An embodiment of the present invention provides a Zener diode, comprising: a substrate; a buried layer formed on at least a part of a first surface of the substrate; an epitaxial layer at least partially formed on the buried layer; and a diffusion layer at least partially formed on the epitaxial layer; wherein a distance is between the diffusion layer and the buried layer.

An embodiment of the present invention provides a Zener diode, comprising: a substrate having a first carrier concentration distribution; an epitaxial layer having a second carrier concentration distribution; a buried layer having a third carrier concentration distribution; and a diffusion layer having a fourth carrier concentration distribution; wherein there is a first carrier concentration difference between the first carrier concentration distribution and the fourth carrier concentration distribution, and there is a second carrier concentration difference between the third carrier concentration distribution and the fourth carrier concentration distribution.

An embodiment of the present invention provides a method for manufacturing Zener diodes, comprising: forming a substrate; forming a buried layer, wherein the buried layer is formed on at least a part of a first surface of the substrate; forming an epitaxial layer, wherein the epitaxial layer at least partially is formed on the buried layer; forming a diffusion layer, wherein the diffusion layer at least partially is formed on at least the epitaxial layer; wherein a distance is between the diffusion layer and the buried layer.

As described above, because the Zener diode of the present invention has a distance between the diffusion layer and the buried layer, that is, the diffusion layer is in contact with the epitaxial layer whose carrier concentration is lower than that of the buried layer, the present invention can reduce the junction capacitance of the Zener diode, so that the Zener diode can be applied to high-speed signal transmission. The carrier concentrations of the diffusion layer and the substrate are both steeply distributed, but the carrier concentration and thickness of the epitaxial layer are both stable and flat. Therefore, by adjusting the carrier concentration and thickness of the epitaxial layer to obtain the corresponding breakdown region range, the breakdown voltage of the Zener diode can be determined. The process is also relatively easy to control for ion implantation. Compared with the method of adjusting ion implantation, the method of adjusting carrier concentration and thickness of the epitaxial layer of the present invention has a wider corresponding breakdown voltage range.

### BRIEF DESCRIPTION OF THE DRAWINGS

FIGS. 1A-1C are cross-sectional views of an embodiment of a Zener diode according to the present invention.

FIG. 2 is a diagram showing a carrier concentration distribution on a cutting line C in FIG. 1 in accordance with an embodiment of a cross-sectional view of a Zener diode of the present invention.

FIG. 3 is a diagram showing the electric field distribution on the cutting line C in FIG. 1 in accordance with an embodiment of a cross-sectional view of a Zener diode of the present invention.

FIG. 4 is a diagram showing a carrier concentration distribution on a cutting line B in FIG. 1 in accordance with an embodiment of a cross-sectional view of a Zener diode of the present invention.

FIG. 5 is a diagram showing the electric field distribution on the cutting line B in FIG. 1 in accordance with an embodiment of a cross-sectional view of a Zener diode of the present invention.

FIG. 6 is a diagram showing the electric field distribution on the cutting line B in FIG. 1 in accordance with an embodiment of a cross-sectional view of a Zener diode of the present invention.

FIG. 7 is a diagram showing the electric field distribution on the cutting line B in FIG. 1 in accordance with an embodiment of a cross-sectional view of a Zener diode of the present invention.

FIG. 8 is another embodiment of a cross-sectional view of a Zener diode of the present invention.

FIG. 9 is another embodiment of a cross-sectional view of a Zener diode of the present invention.

FIG. 10 is a diagram showing a method for manufacturing a Zener diode according to the present invention.

FIG. 11 shows various structural changes of the method for manufacturing a Zener diode according to the present invention.

### DETAILED DESCRIPTION

Various embodiments will be described below, and those of ordinary skill in the art can easily understand the spirits and principles of the present disclosure referring to this specification accompanied by the drawings. However, although some particular embodiments will be specifically illustrated herein, these embodiments are only exemplary, and are not to be regarded as limiting or exhaustive in all respects. Therefore, for those of ordinary skill in the art, various changes and modifications to the present disclosure should be obvious and can be easily achieved without departing from the spirits and principles of the present disclosure.

In each embodiment of the present invention, the first conductivity type is defined as N-type, and the second conductivity type is defined as P-type. However, the conductivity type definitions of each embodiment are for better illustrating the present invention and do not limit the application scope of the present invention.

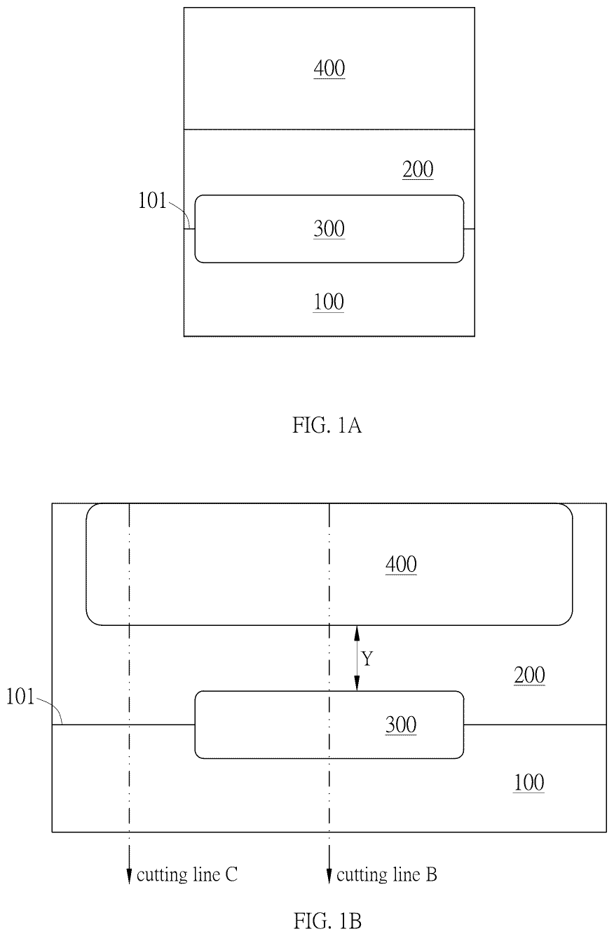

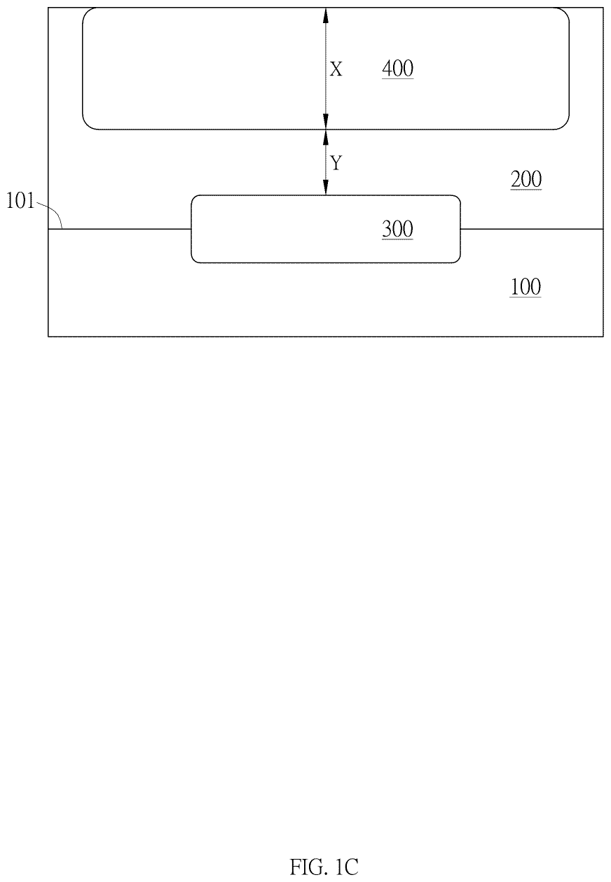

Referring to FIG. 1A, FIG. 1A is a cross-sectional view of a Zener diode according to an embodiment of the present invention. This embodiment has a substrate 100, a buried layer 300, an epitaxial layer 200, and a diffusion layer 400. The substrate 100 can be one of the first and second conductivity types. In the present embodiment, when the conductivity type of the substrate 100 is selected from the first conductivity type (i.e., N-type), the conductivity type of the buried layer 300 is selected from the same conductivity type as the substrate 100, and the buried layer 300 is formed on at least a portion of the first surface 101 of the substrate 100. The conductivity type of the epitaxial layer 200 is selected from the same conductivity type as the substrate 100, and the conductivity type of the diffusion layer 400 is selected from the other conductivity type of the substrate 100, and the diffusion layer 400 is at least partially formed on the epitaxial layer 200. It should be noted that the cross-sectional width of the diffusion layer 400 can be adjusted according to different doping methods (for example, ion implantation, thermal drive-in, but not limited thereto). The carrier concentration of the epitaxial layer 200 is less than the carrier concentration of the substrate 100, and the epitaxial layer 200 is at least partially formed on the buried layer 300. It should be noted that the epitaxial layer 200 can also be formed in other areas of the first surface 101 of the substrate 100, and the present invention is not limited thereto. In one embodiment as shown in FIG. 1B, the cross-sectional width of the diffusion layer 400 can be less than or equal to the cross-sectional width of the epitaxial layer 200. The buried layer 300 is at least partially formed on a portion of the first surface 101 of the substrate 100, and the cross-sectional width of the buried layer 300 is smaller than the cross-sectional width of the diffusion layer 400. By adjusting the carrier concentration and thickness of the epitaxial layer 200, the buried layer 300 is not in direct contact with the diffusion layer 400 and a distance Y is generated. In a preferred embodiment, the epitaxial carrier concentration can be as low as 1e13 cm^{\hat{ }-3} and as high as 5e18 cm^{\hat{ }-3.}; the epitaxial carrier thickness can be as low as 1 um and as high as 200 um. Since the diffusion layer 400 is in contact with the epitaxial layer 200 having a lower carrier concentration than the buried layer 300, the present invention can reduce the junction capacitance of the Zener diode, that the Zener diode can be applied to high-speed signal transmission. From the process aspect, the distance Y between the buried layer 300 and the diffusion layer 400 can be adjusted by adjusting the carrier concentration and thickness of the epitaxial layer 200. Compared to adjusting the ion implantation concentration and thickness range of the buried layer 300, adjusting the carrier concentration and thickness of the epitaxial layer 200 can more accurately control the distance Y and provide a larger operating range. Therefore, the method of adjusting the carrier concentration and thickness of the epitaxial layer of the present invention has a wider range of corresponding breakdown voltages and is easier to adjust than the method of adjusting ion implantation.

In one embodiment, the range of the distance Y can also be further adjusted by changing the thickness of the diffusion layer 400. Specifically, referring to the embodiment shown in FIG. 1C, the distance Y between the buried layer 300 and the diffusion layer 400 can be adjusted accordingly by changing the diffusion layer thickness X of the diffusion layer 400. For example, when the diffusion layer thickness X increases, the corresponding distance Y decreases accordingly; when the diffusion layer thickness X decreases, the corresponding distance Y increases accordingly. At this time, the distance Y between the buried layer 300 and the diffusion layer 400 is substantially equal to the remaining thickness of the epitaxial layer 200 after the diffusion layer 400 is disposed. In this embodiment, after the epitaxial layer 200 is formed, the range of the distance Y is further adjusted by changing the diffusion layer thickness X of the diffusion layer 400, so that the method of adjusting the distance Y between the buried layer 300 and the diffusion layer 400 of the present invention is more flexible.

In terms of carrier concentration distribution, refer to FIG. 2, which is a carrier concentration distribution diagram on the cutting line C in FIG. 1B of an embodiment of a cross-sectional view of a Zener diode of the present invention, wherein the horizontal axis is the position of each structure of the Zener diode corresponding to the cutting line C on the distribution diagram, and the vertical axis is the carrier concentration distribution of each structure of the Zener diode corresponding to the cutting line C on the distribution diagram. The substrate 100 has a first carrier concentration distribution 110, the diffusion layer 400 has a fourth carrier concentration distribution 410, and the epitaxial layer 200 has a second carrier concentration distribution 210. In FIG. 1C, there is no buried layer 300 on the cutting line C (i.e., only the epitaxial layer 200 separates the diffusion layer 400 and the substrate 100). Therefore, the corresponding breakdown region is formed on the epitaxial layer 200 between the diffusion layer 400 and the substrate 100, and the breakdown region range is the W_C range (i.e., the first carrier concentration difference) formed by the intersection of the second carrier concentration distribution 210 and the fourth carrier concentration distribution 410 and the intersection of the second carrier concentration distribution 210 and the first carrier concentration distribution 110 in FIG. 2.

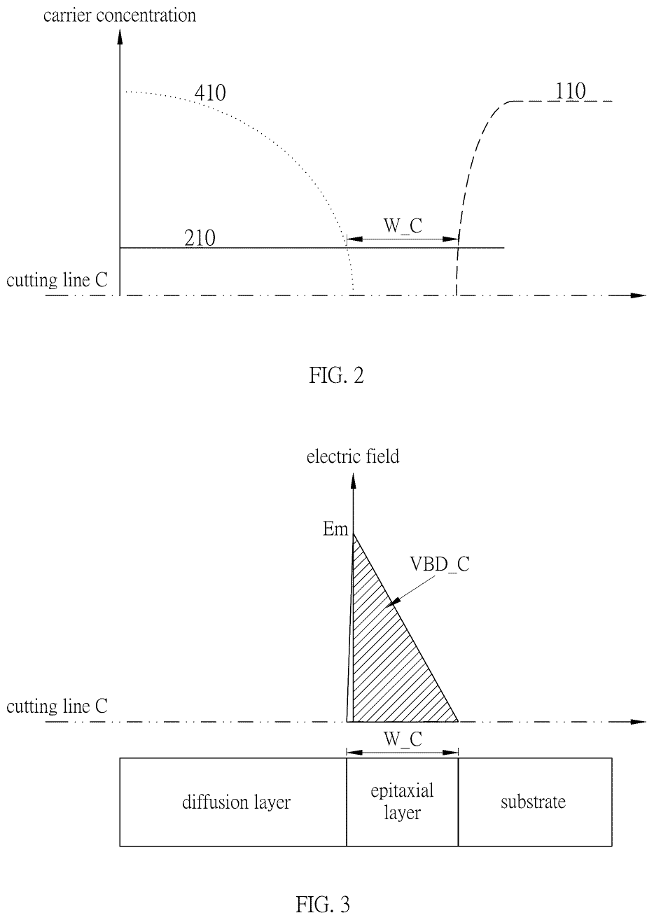

Referring to FIG. 3, FIG. 3 is an electric field distribution diagram on the cutting line C in FIG. 1B of an embodiment of a cross-sectional view of a Zener diode of the present invention. The horizontal axis of FIG. 3 is the position of each structure of the Zener diode corresponding to the cutting line C on the distribution diagram (refer to FIG. 2), and the vertical axis is the electric field intensity of each structure of the Zener diode corresponding to the cutting line C on the distribution diagram. When the supply voltage is applied to both ends of the substrate 100 and the diffusion layer 400 as shown in FIG. 1B (for example, the substrate 100 is the voltage input end and the diffusion layer 400 is the ground end, but not limited thereto), the voltage on the substrate 100 is a forward voltage relative to the diffusion layer 400, and the epitaxial layer 200 corresponding to the first carrier concentration difference W_C will be fully depleted, and a maximum electric field Em will occur at the junction of the diffusion layer 400 and the epitaxial layer 200. When sufficient voltage is applied, avalanche breakdown will occur. In other words, the current flowing through the substrate 100 and the diffusion layer 400 will suddenly increase, causing the Zener diode to collapse and generate a breakdown voltage. The breakdown voltage VBD_C on the cutting line C is the area formed by the first carrier concentration interval (W_C) and the maximum electric field (Em) in FIG. 3.

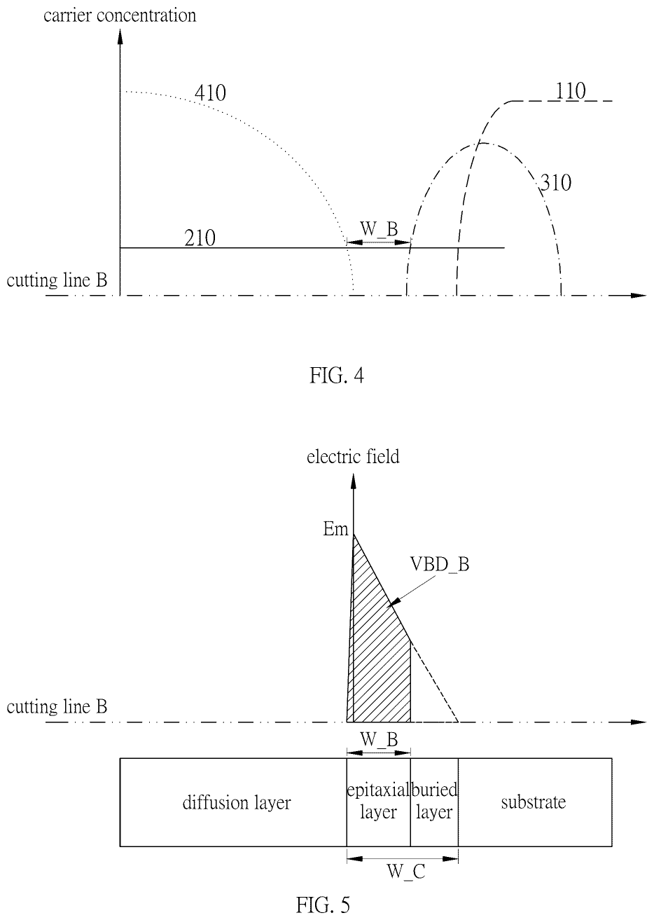

With respect to the cutting line B in FIG. 1B, please refer to FIG. 4, which is a diagram showing the carrier concentration distribution on the cutting line B in FIG. 1B of an embodiment of a cross-sectional view of a Zener diode of the present invention. Wherein FIG. 4 is the position of each structure of the Zener diode corresponding to the cutting line B on the distribution diagram, and the vertical axis is the carrier concentration distribution of each structure of the Zener diode corresponding to the cutting line B on the distribution diagram. As shown in FIG. 4, the substrate 100 has a first carrier concentration distribution 110, the diffusion layer 400 has a fourth carrier concentration distribution 410, the buried layer 300 has a third carrier concentration distribution 310, and the buried layer 300 is provided on the cutting line B to separate the diffusion layer 400 and the substrate 100. The corresponding breakdown region is formed on the epitaxial layer 200 between the diffusion layer 400 and the buried layer 300, and the breakdown region range is the W_B range (i.e., the second carrier concentration difference) formed by the intersection of the second carrier concentration distribution 210 and the fourth carrier concentration distribution 410 and the intersection of the second carrier concentration distribution 210 and the third carrier concentration distribution 310. As can be understood from FIG. 2, because the third carrier concentration distribution 310 intersects with the second carrier concentration distribution 210 earlier than the first carrier concentration distribution 110, the breakdown region width W_B on the cutting line B is smaller than the breakdown region width W_C on the cutting line C.

From the perspective of electric field distribution, refer to FIG. 5, which is an electric field distribution diagram on the cutting line B in FIG. 1B of an embodiment of a cross-sectional view of a Zener diode of the present invention, wherein the horizontal axis of FIG. 5 is the position of each structure of the Zener diode corresponding to the cutting line B on the distribution diagram (refer to FIG. 4) , and the vertical axis is the electric field intensity of each structure of the Zener diode corresponding to the cutting line B on the distribution diagram. When the supply voltage is applied to both ends of the substrate 100 and the diffusion layer 400 as shown in FIG. 1B, the voltage on the substrate 100 is a forward voltage relative to the diffusion layer 400, and the epitaxial layer 200 corresponding to the first carrier concentration difference W_B will be fully depleted, and a maximum electric field Em will occur at the junction of the diffusion layer 400 and the epitaxial layer 200, and avalanche breakdown will occur at this time. In other words, the current flowing through the substrate 100 and the diffusion layer 400 will suddenly increase, causing the Zener diode to collapse and generate a breakdown voltage. The breakdown voltage VBD_B on the cutting line B is the area formed by the second carrier concentration interval (W_B) and the maximum electric field (Em) in FIG. 5.

In summary, referring to FIG. 1B to FIG. 5, since the width W_B of the breakdown voltage region in FIG. 4 is smaller than the width W_C of the breakdown voltage region in FIG. 2, that is, under the same maximum electric field Em, the generated breakdown voltage VBD_B will also be smaller than VBD_C. Therefore, when a voltage is applied to the substrate 100 of the present embodiment as a forward voltage relative to the diffusion layer 400, the Zener diode of the present invention will first collapse in the epitaxial layer 200 region between the diffusion layer 400 and the buried layer 300 (for example, the range crossed by the cutting line B in FIG. 1B), while the region without the buried layer 300 (for example, the range crossed by the cutting line C in FIG. 1B) will not collapse. Therefore, the breakdown region of the Zener diode will be controlled in the epitaxial layer 200 between the diffusion layer 400 and the buried layer 300. That is to say, the breakdown region of the Zener diode can be caused to occur at the plane junction, because the area of the plane junction is much larger than the area of the edge. Therefore, the present invention can effectively suppress the edge effect and improve the anti-static discharge capability of the Zener diode. The carrier concentration distributions of the diffusion layer 400 and the substrate 100 in FIG. 2 and FIG. 4 are both steep, but the carrier concentration distribution of the epitaxial layer 200 is both stable and flat. Therefore, by adjusting the carrier concentration of the epitaxial layer 200 to obtain the corresponding breakdown voltage region, the overall breakdown voltage of the Zener diode can be determined. In terms of process, the method of adjusting the carrier concentration of the epitaxial layer 200 is also relatively easy to control for the ion implantation method.

Referring to FIG. 6, FIG. 6 is an electric field distribution diagram of an embodiment of a cross-sectional view of a Zener diode of the present invention on the cutting line B of FIG. 1B. In this embodiment, the carrier concentration of the epitaxial layer 200 is increased (compared to the embodiment of FIG. 5), and a voltage is supplied to both ends of the substrate 100 and the diffusion layer 400 of the embodiment of FIG. 1B, wherein the substrate 100 is the input end and the diffusion layer 400 is the ground end. At this time, the voltage on the substrate 100 is a forward voltage relative to the diffusion layer 400, and the epitaxial layer 200 corresponding to the second carrier concentration difference W_B will be fully depleted, and the maximum electric field Em will occur at the junction of the diffusion layer 400 and the epitaxial layer 200, and an avalanche breakdown will occur at this time. In the present embodiment, since the carrier concentration of the epitaxial layer 200 is increased, the slope of the corresponding electric field distribution is also increased, and the breakdown voltage VBD_B′ on the cutting line B is the area formed by the second carrier concentration difference (W_B) and the maximum electric field (Em) in FIG. 6. It can be seen from FIG. 6 that the area of the breakdown voltage VBD_B′ is reduced compared to that in FIG. 5, so the breakdown voltage VBD_B′ is also reduced compared to that in FIG. 5, thereby achieving the effect of adjusting the epitaxial carrier concentration distribution and adjusting the corresponding breakdown voltage accordingly.

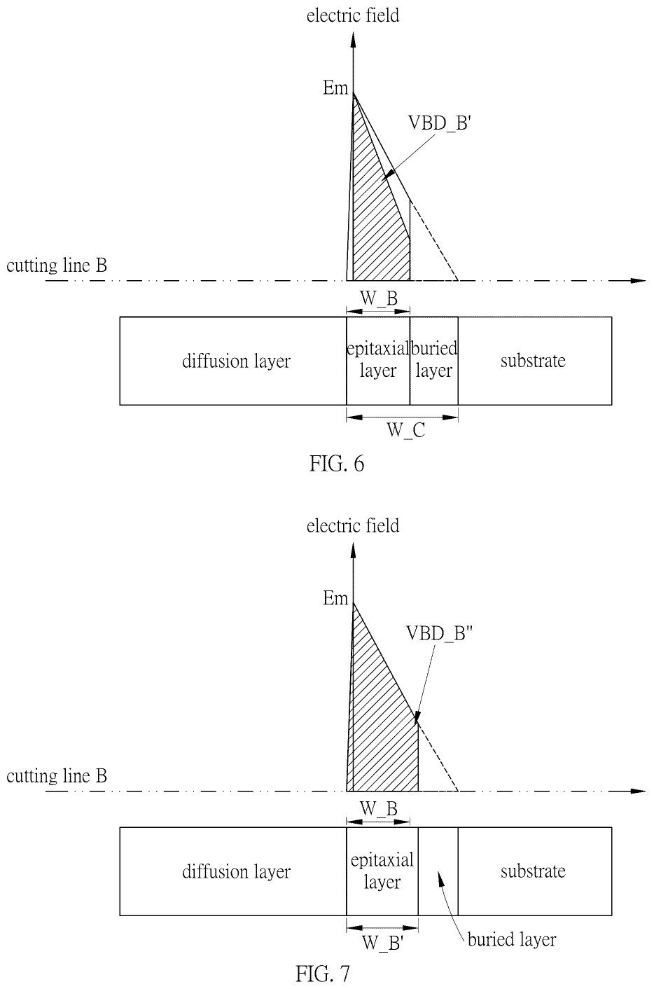

Referring to FIG. 7, FIG. 7 is an electric field distribution diagram of an embodiment of a cross-sectional view of a Zener diode of the present invention on the cutting line B of FIG. 1B. In this embodiment, the carrier thickness of the epitaxial layer 200 is increased, and a voltage is supplied to both ends of the substrate 100 and the diffusion layer 400 of the embodiment of FIG. 1B, wherein the substrate 100 is the input end and the diffusion layer 400 is the ground end. At this time, the voltage on the substrate 100 is a forward voltage relative to the diffusion layer 400. In this embodiment, due to the increase in the carrier thickness of the epitaxial layer 200, the corresponding depletion area is also increased, and the second carrier concentration difference is increased from W_B to W_B′. The epitaxial layer 200 corresponding to the second carrier concentration difference W_B′ will be fully depleted, and the maximum electric field Em will occur at the junction of the diffusion layer 400 and the epitaxial layer 200, and an avalanche breakdown will occur at this time. The breakdown voltage VBD_B″ on the cutting line B is the area formed by the second carrier concentration distribution (W_B′) and the maximum electric field (Em) in FIG. 7. It can be seen from FIG. 7 that the area of the breakdown voltage VBD_B″ is increased compared to that in FIG. 5, so the breakdown voltage VBD_B″ is also increased compared to that in FIG. 5, thereby achieving the effect of adjusting the epitaxial carrier thickness distribution and adjusting the corresponding breakdown voltage accordingly.

Referring to FIG. 8, FIG. 8 is another embodiment of the Zener diode of the present invention. FIG. 8 is based on the structure of FIG. 1A to FIG. 1C, and a first doping region 201 is provided on the diffusion layer 400. The first doping region 201 is doped with a first carrier, wherein the conductivity type of the first carrier is selected from another conductivity type of the diffusion layer 400. By providing the first doping region 201 on the diffusion layer 400, the capacitance of the present invention can be reduced. When the voltage is supplied to the two ends of the substrate 100 and the first doping region 201 of this embodiment, wherein the substrate 100 is the input end and the first doping region 201 is the ground end, the voltage on the substrate 100 is a forward voltage relative to the first doping region 201. By adjusting the carrier concentration and thickness of the epitaxial layer 200, the breakdown region can be controlled by the epitaxial layer 200 between the diffusion layer 400 and the buried layer 300. That is, the electric field distribution at the planar junction and the breakdown voltage determination method are the same as those in FIG. 1A to FIG. 7, and the breakdown voltage of the overall component of this embodiment is the aforementioned breakdown voltage plus the forward voltage of 0.7 volts from the first doping region 201 to the diffusion layer 400, which can also achieve the purpose of the present invention.

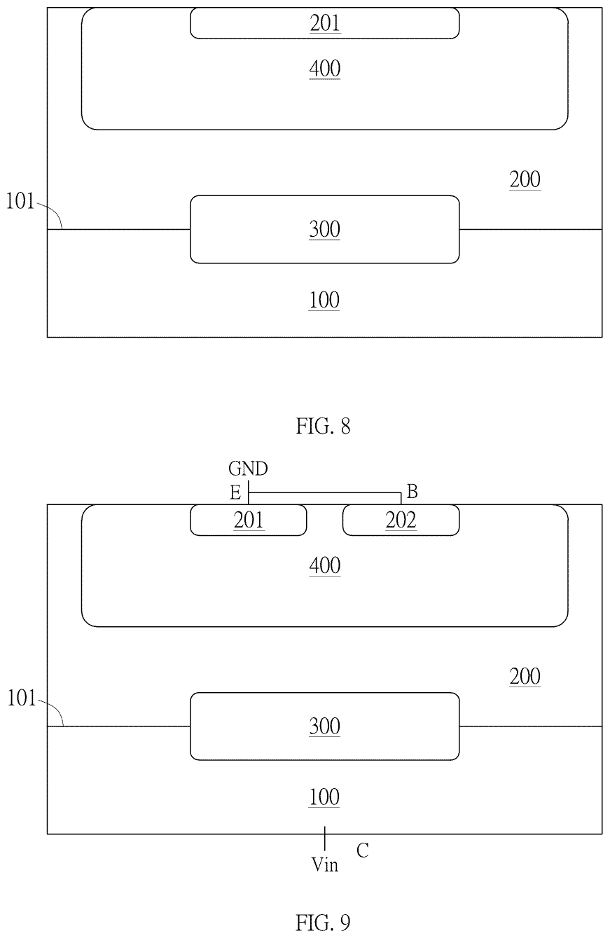

Referring to FIG. 9, FIG. 9 is another embodiment of the Zener diode of the present invention. FIG. 9 can be equivalent to an NPN element. Based on the structures of FIG. 1A to FIG. 1C, a first doping region 201 and a second doping region 202 are respectively arranged on the diffusion layer 400. The first doping region 201 is doped with a first carrier, and the second doping region 202 is doped with a second carrier. The conductivity type of the first carrier is selected from another conductivity type of the diffusion layer 400, and the conductivity type of the second carrier is selected from the same conductivity type of the diffusion layer 400, wherein the base (corresponding to the second doping region 202) and the emitter (corresponding to the first doping region 201) are ground ends, and the collector (corresponding to the substrate 100) is an input end. When a voltage is supplied to the collector and emitter of this embodiment, the voltage on the collector is a positive voltage relative to the emitter. And by adjusting the carrier concentration and thickness of the epitaxial layer 200, the breakdown region can be controlled by the epitaxial layer 200 between the diffusion layer 400 and the buried layer 300. That is, the electric field distribution at the planar junction and the breakdown voltage determination method are the same as those in FIG. 1A to FIG. 7, which can also achieve the purpose of the present invention. Furthermore, the present invention can be made into NPN or PNP components and applied to more circuits.

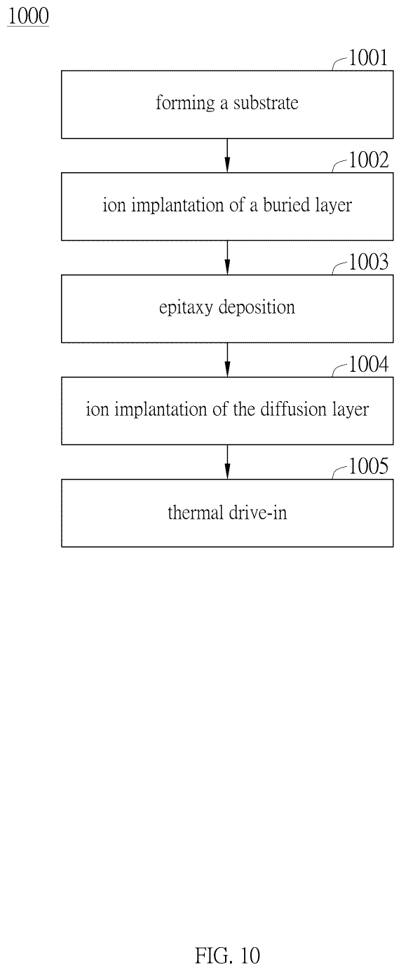

Referring to FIG. 10, FIG. 10 is the method 1000 for manufacturing a Zener diode according to the present invention, which includes step 1001, forming a substrate 100, wherein the substrate 100 is formed by one of a first conductivity type and a second conductivity type. Step 1002, ion implantation of a buried layer, which forms a buried layer 300 by ion implantation, wherein the conductive type of the buried layer 300 is the same as the conductive type of the substrate 100. Step 1003, epitaxy deposition, which forms an epitaxial layer 200 through epitaxy deposition, wherein the conductivity type formed by the epitaxial layer 200 is the same as the conductivity type formed by the substrate 100, and the carrier concentration of the epitaxial layer 200 is less than the carrier concentration of the substrate 100. In a preferred embodiment, the epitaxial carrier concentration can be as low as 1e13 cm^{\hat{ }-3} and as high as 5e18 cm^{\hat{ }-3}; the epitaxial carrier thickness can be as low as 1 um and as high as 200 um. Step 1004, ion implantation of the diffusion layer. The diffusion layer 400 is formed by ion implantation, wherein the conductivity type of the diffusion layer 400 is selected from another conductivity type formed on the substrate 100. Step 1005, thermal drive-in to make the doping ions in the diffusion layer 400 more uniformly distributed.

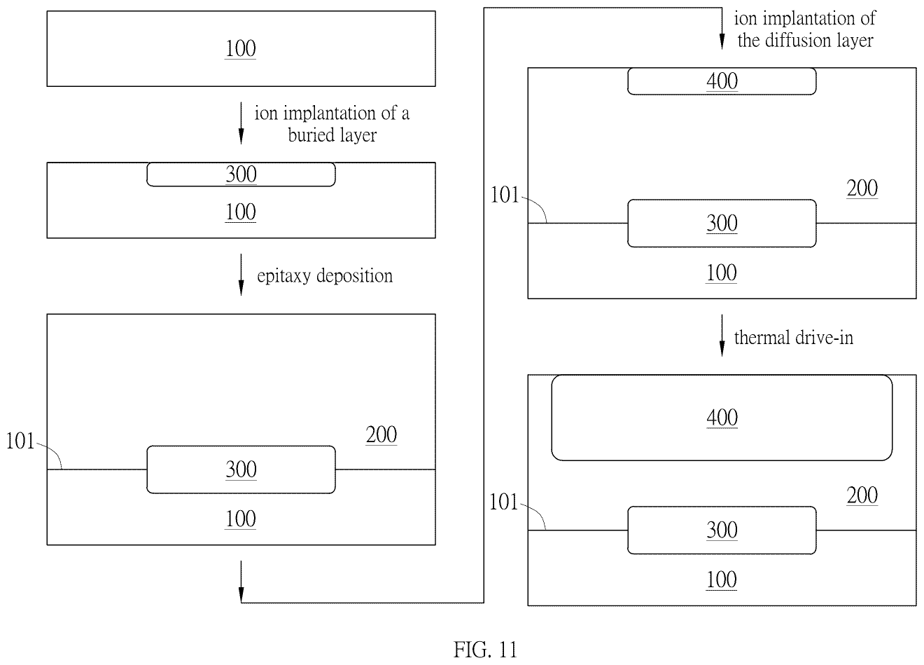

Referring to FIG. 11, FIG. 11 shows various structural changes of the manufacturing method of the Zener diode of the present invention. The formation sequence is substrate 100→buried layer 300→epitaxial layer 200→diffusion layer 400. From FIG. 11, it can be understood that the manufacturing method of the present invention comprises: forming a substrate 100; forming a buried layer 300, wherein the buried layer 300 is formed on at least a part of a first surface 101 of the substrate 100; forming an epitaxial layer 200, wherein the epitaxial layer 200 is formed on at least the buried layer 300; forming a diffusion layer 400, wherein the diffusion layer 400 is formed on at least the epitaxial layer 200; wherein there is a distance between the diffusion layer 400 and the buried layer 300.

In summary, according to the Zener diodes of various embodiments of the present invention, whose diffusion layer is in contact with the epitaxial layer whose carrier concentration is lower than that of the buried layer, the present invention can reduce the junction capacitance of the Zener diode, allowing the Zener diode to be applied to high-speed signal transmission. The carrier concentrations of the diffusion layer and the substrate are both steeply distributed, but the carrier concentration and thickness of the epitaxial layer are both stable and flat. Therefore, by adjusting the carrier concentration and thickness of the epitaxial layer to obtain the corresponding breakdown region range, the breakdown voltage of the Zener diode can be determined. The process is also relatively easy to control for ion implantation. According to the embodiments of the present invention, the applicable aspects are not limited to the examples specifically listed herein.

The above description contains only some preferred embodiments of the present invention. Among them, the proportions and relative proportions of each component or part shown in the drawings may be exaggerated or changed for the purpose of clear display or convenience of explanation, and those with ordinary skill in the art should understand that they are not intended to be specific dimensional limitations. In addition, it should be noted that various changes and modifications can be made to the present invention without departing from the spirit and principles of the present invention. Those of ordinary skill in the art should understand that the present invention is defined by the appended claims, and under the spirit of the present invention, all possible replacements, combinations, modifications, diversions and other changes would not exceed the scope of the present invention defined by the appended claims.

What is claimed is:

1. A Zener diode, comprising:
a substrate;
a buried layer formed on at least a part of a first surface of the substrate;
an epitaxial layer, the epitaxial layer at least partially formed on the buried layer; and
a diffusion layer at least partially formed on the epitaxial layer;
wherein a distance is between the diffusion layer and the buried layer.

2. The Zener diode of claim 1, wherein the distance is determined by a remaining thickness of the epitaxial layer after the diffusion layer is disposed.

3. The Zener diode of claim 1, wherein the substrate has a first carrier concentration distribution, and the diffusion layer has a fourth carrier concentration distribution; wherein a first carrier concentration difference is provided between the first carrier concentration distribution and the fourth carrier concentration distribution.

4. The Zener diode of claim 3, wherein the epitaxial layer also has a second carrier concentration distribution, and the buried layer also has a third carrier concentration distribution; wherein a second carrier concentration difference is provided between the third carrier concentration distribution and the fourth carrier concentration distribution.

5. The Zener diode of claim 4, wherein the first carrier concentration difference is determined by a relative distance between an intersection of the second carrier concentration distribution and the first carrier concentration distribution and an intersection of the second carrier concentration distribution and the fourth carrier concentration distribution.

6. The Zener diode of claim 4, wherein the second carrier concentration difference is determined by a relative distance between an intersection of the second carrier concentration distribution and the third carrier concentration distribution and an intersection of the second carrier concentration distribution and the fourth carrier concentration distribution.

7. The Zener diode of claim 1, wherein a cross-sectional width of the buried layer is smaller than the cross-sectional width of the diffusion layer.

8. The Zener diode of claim 1, wherein the diffusion layer is provided with a first doping region, the first doping region is doped with a first carrier, and a conductivity type of the first carrier is different from that of the diffusion layer.

9. The Zener diode of claim 8, the diffusion layer is further provided with a second doping region, the second doping region is doped with a second carrier, and the conductivity type of the second carrier is the same as that of the diffusion layer.

10. A Zener diode, comprising:
a substrate having a first carrier concentration distribution;
an epitaxial layer having a second carrier concentration distribution at least partially overlapping the first carrier concentration distribution;
a buried layer having a third carrier concentration distribution at least partially overlapping the first carrier concentration distribution and the second carrier concentration distribution respectively; and
a diffusion layer having a fourth carrier concentration distribution at least partially overlapping the third carrier concentration distribution;
wherein there is a first carrier concentration difference between the first carrier concentration distribution and the fourth carrier concentration distribution, and there is a second carrier concentration difference between the third carrier concentration distribution and the fourth carrier concentration distribution.

11. The Zener diode of claim 10, wherein the first carrier concentration difference is determined by a relative distance between an intersection of the second carrier concentration distribution and the first carrier concentration distribution and an intersection of the second carrier concentration distribution and the fourth carrier concentration distribution.

12. The Zener diode of claim 10, wherein the second carrier concentration difference is determined by a relative distance between an intersection of the second carrier concentration distribution and the third carrier concentration distribution and an intersection of the second carrier concentration distribution and the fourth carrier concentration distribution.

13. A method for manufacturing Zener diode, comprising:
forming a substrate;
forming a buried layer, wherein the buried layer formed on at least a part of a first surface of the substrate;
forming an epitaxial layer, wherein the epitaxial layer at least partially formed on the buried layer;
forming a diffusion layer, wherein the diffusion layer at least partially formed on at least the epitaxial layer;
wherein a distance is between the diffusion layer and the buried layer.

14. The method of claim 13, further comprising: when forming the distance, the distance is determined by a remaining thickness of the epitaxial layer after the diffusion layer is disposed.

15. The method of claim 14, further comprising: when forming the substrate, a first carrier concentration distribution is generated; when forming the epitaxial layer, a second carrier concentration distribution is generated.

16. The method of claim 15, further comprising: when forming the buried layer, a third carrier concentration distribution is generated; when forming the diffusion layer, a fourth carrier concentration distribution is generated;
wherein a first carrier concentration difference is provided between the first carrier concentration distribution and the fourth carrier concentration distribution;
wherein a second carrier concentration difference is provided between the third carrier concentration distribution and the fourth carrier concentration distribution.

17. The method of claim 16, further comprising:
wherein the first carrier concentration difference is determined by a relative distance between an intersection of the second carrier concentration distribution and the first carrier concentration distribution and an intersection of the second carrier concentration distribution and the fourth carrier concentration distribution.

18. The method of claim 16, further comprising:
wherein the second carrier concentration difference is determined by a relative distance between an intersection of the second carrier concentration distribution and the third carrier concentration distribution and an intersection of the second carrier concentration distribution and the fourth carrier concentration distribution.

19. The method of claim 14, further comprising: wherein a cross-sectional width when forming the buried layer is smaller than the cross-sectional width when forming the diffusion layer.
